(19) United States
(12) Patent Application Publication
(10) Pub. No.: US 2024/0202407 A1
(43) Pub. Date: Jun. 20, 2024

(54) DRILL BIT OPTIMIZER

(71) Applicant: Schlumberger Technology Corporation, Sugar Land, TX (US)

(72) Inventors: Riadh Boualleg, Stonehouse (GB); Andrew Poor, Sugar Land, TX (US); Ling Li, Clamart (FR); Chris Bogath, Katy, TX (US); Telman Maghrebi, Stonehouse (GB); James Masdea, Houston, TX (US)

(21) Appl. No.: 18/531,797

(22) Filed: Dec. 7, 2023

Related U.S. Application Data
(60) Provisional application No. 63/387,578, filed on Dec. 15, 2022.

(51) Int. Cl. G06F 30/27

(52) U.S. Cl. CPC G06F 30/27; E21B 49/00; E21B 2200/20

(57) ABSTRACT

A method for optimizing a drill bit for a drilling operation includes training a plurality of machine learning (ML) models with historical drilling data to obtain a corresponding plurality of trained ML models; obtaining drilling operation parameters for the drilling operation; generating drill bit parameters for each of a plurality of potential drill bit configurations; inputting the obtained drilling operation parameters and the generated drill bit parameters into the plurality of trained ML models to estimate a corresponding plurality of drill bit performance metrics; and selecting an optimum drill bit configuration from the set of potential drill bit configurations based on the estimated drill bit performance metrics obtained from plurality of trained ML models.

### CROSS REFERENCE TO RELATED APPLICATIONS

This application claims priority to U.S. Provisional Application Ser. No. 63/387,578, which was filed on Dec. 15, 2022, and is incorporated herein by reference in its entirety.

### BACKGROUND

Rotary drilling is commonly employed to drill subterranean wellbores. In such operations, a drill bit including numerous sharp cutting elements is deployed at the lower end of a drill string. Rotation of the drill string and the application of a downhole directed force (commonly referred to in the industry as weight on bit) causes the drill bit to cut the formation rock and thereby drill the wellbore.

In modern drilling operations, the drill bit generally serves at least two critical functions. First, the drill bit is intended to transfer rotary energy from the drill string to the formation rock via the sharp cutting elements on the bit to thereby bore through the formation and drill the wellbore. Second, the drill bit is further intended to dispense drilling fluid from the drill string to the wellbore (e.g., via jets or orifices in the bit) to lubricate the cutting elements and wash cuttings away from the cutting interface.

Various characteristics of the drill bit have long been understood to significantly influence the drilling operation, for example, to impact the rate of penetration, the steerability, and the stability of the drilling operation. The characteristics of the drill bit are commonly selected with features of the drill string and the formation properties in mind, for example, to promote a quality drilling operation. Moreover, owing to the high costs of drilling and operating a drilling rig, proper drill bit selection may provide substantial economic benefits. While efforts to optimize drill bits have been ongoing for decades, there remains room for further improvements.

### SUMMARY

Methods and systems for optimizing a drill bit are disclosed. In one example embodiment, a method for optimizing a drill bit for a drilling operation includes training a plurality of machine learning (ML) models with historical drilling data to obtain a corresponding plurality of trained ML models; obtaining drilling operation parameters for the drilling operation; generating drill bit parameters for each of a plurality of potential drill bit configurations; inputting the obtained drilling operation parameters and the generated drill bit parameters into the plurality of trained ML models to estimate a corresponding plurality of drill bit performance metrics; and selecting an optimum drill bit configuration from the set of potential drill bit configurations based on the estimated drill bit performance metrics obtained from plurality of trained ML models.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

For a more complete understanding of the disclosed subject matter, and advantages thereof, reference is now made to the following descriptions taken in conjunction with the accompanying drawings, in which:

FIG. 1 depicts an example drilling rig including an example system for optimizing a drill bit.

FIG. 2 depicts an example drill bit that may be optimized using the depicted system.

FIG. 3 schematically depicts one example of a relationship between three key drill bit performance indicators.

FIG. 4 depicts an example block diagram of machine learning (ML) model training.

FIG. 5 depicts a flowchart of one example method for optimizing a drill bit for a particular drilling operation.

FIG. 6A depicts an example triangular representation of three key drill bit performance indicators for one example drill bit configuration.

FIG. 6B depicts an example triangular representation of three key drill bit performance indicators for three example drill bit configurations.

### DETAILED DESCRIPTION

Embodiments of this disclosure include systems and methods for optimizing a drill bit. One example method includes training a plurality of machine learning (ML) models with historical drilling data to obtain a corresponding plurality of trained ML models, wherein each of the trained ML models is configured to estimate a corresponding drill bit performance metric; obtaining drilling operation parameters for the drilling operation, wherein the drilling operation parameters include at least one of drilling parameters, formation parameters, and bottom hole assembly parameters; generating drill bit parameters for each of a plurality of potential drill bit configurations; inputting the obtained drilling operation parameters and the generated drill bit parameters into the plurality of trained ML models to estimate a corresponding plurality of drill bit performance metrics; and selecting an optimum drill bit configuration from the set of potential drill bit configurations based on the estimated drill bit performance metrics obtained from plurality of trained ML models.

Example embodiments disclosed herein may provide various technical advantages and improvements over the prior art. For example, the disclosed embodiments may advantageously enable drill bit designers to optimize a drill bit design based on real world data rather than purely relying on physical models. The disclosed embodiments, may further enable a design lead time to be shortened from a period of weeks to days. Moreover, the disclosed embodiments may further enable drill bit designers to make informed decisions regarding drill bit performances and may therefore improve design efficiency.

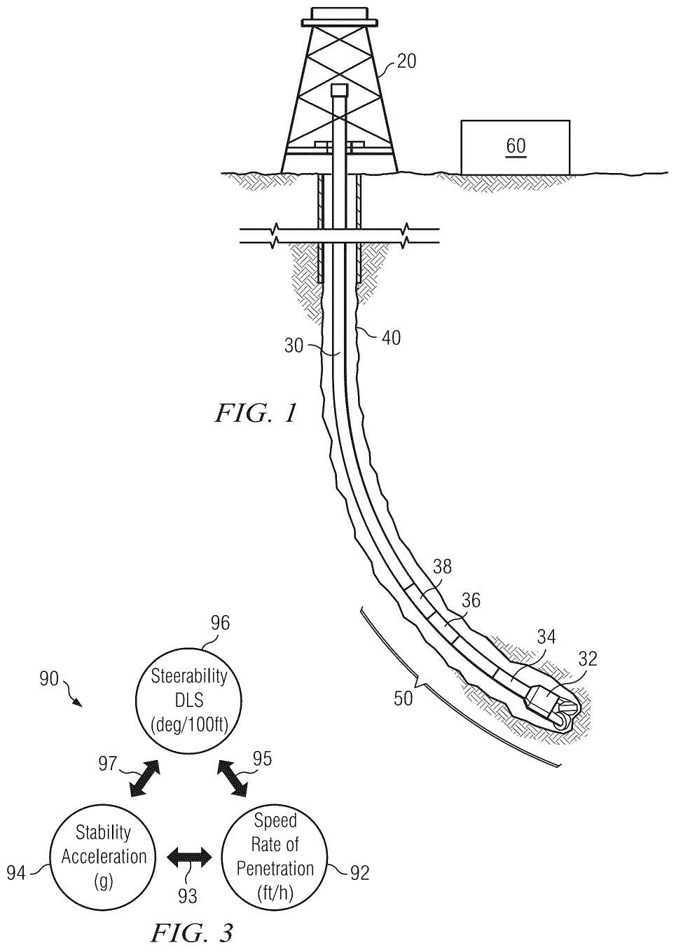

FIG. 1 depicts an example drilling rig 20 including a system 60 for optimizing a drill bit. The drilling rig 20 may be positioned over a subterranean formation (not shown) and may be configured for drilling a geothermal well or a hydrocarbon exploration and/or production well. The rig 20 may include, for example, a derrick and a hoisting apparatus (also not shown) for raising and lowering a drill string 30, which, as shown, extends into wellbore 40 and includes, for example, a drill bit 32 (such as a drill bit, optimized using system 60), a steering tool 34 (such as a rotary steerable tool), and optional logging while drilling (LWD) 36 and measurement while drilling (MWD) 38 tools. In this type of system, the wellbore 40 may be formed in the subsurface formations by rotary drilling in a manner that is well-known to those of ordinary skill in the art (e.g., via well-known directional drilling techniques). Those of ordinary skill in the art given the benefit of this disclosure will appreciate, however, that the present invention also finds application in drilling applications other than conventional rotary drilling (e.g., mud-motor based directional drilling), and is not limited to land-based rigs.

The disclosed embodiments may advantageously be implemented with a drill string including a rotary steerable tool. Various rotary steerable tool configurations are known in the art including various steering mechanisms for controlling the direction of drilling. For example, the PowerDrive rotary steerable systems (available from SLB) fully rotates with the drill string. The PowerDrive Xceed makes use of an internal steering mechanism that do not require contact with the borehole wall and enables the tool body to fully rotate with the drill string. The PowerDrive X5, X6, and Orbit rotary steerable systems make use of mud actuated blades (or pads) that contact the borehole wall. The PowerDrive Archer makes use of a lower steering section joined at an articulated swivel with an upper section. Advantageous embodiments may make use of a steerable drill bit (such as the NeoSteer at bit steerable system available from SLB) in which the steering elements (pads) are integrated into the drill bit body. Notwithstanding, the disclosed embodiments are not limited to use with any particular steering tool configuration.

As is known to those of ordinary skill, the drill string 30 may be rotated, for example, at the surface and/or via a downhole deployed mud motor to drill the well. A pump may deliver drilling fluid to the interior of the drill string 30 thereby causing the drilling fluid to flow downwardly through the drill string 30. The drilling fluid exits the drill string 30, e.g., via ports in a drill bit 32, and then circulates upwardly through the annulus region between the outside of the drill string 30 and the wall of the wellbore 40. In this known manner, the drilling fluid lubricates the drill bit 32 and carries formation cuttings up to the surface.

Various sensors may be located about the wellsite to collect data (or drilling parameters) related to the drilling operation, such as standpipe pressure, pump pressure, hook load, wellbore depth, surface torque, rotary rpm, among others. The bottom hole assembly (BHA) 50 may also include downhole sensors disposed in the drill bit, the steering tool 34, the LWD tool 36, or the MWD tool 38 to provide information about downhole conditions, such as wellbore pressure, weight on bit, torque on bit, or attitude (inclination and azimuth), collar rpm, tool temperature, annular temperature, and toolface, among others. These sensors (e.g., both uphole and downhole sensors) may be configured to provide data to the system 60 for optimizing the drill bit 32 (e.g., for a subsequent drilling operation).

With continued reference to FIG. 1, in example embodiments, the system 60 may be deployed at the rig site (e.g., in an onsite laboratory as depicted) or offsite. The disclosed embodiments are, of course, not limited in this regard. The system 60 may include computer hardware and software configured to receive drill bit parameters, drilling parameters, and formation parameters and to evaluate the received input to estimate, for example, rate of penetration (ROP), drill bit steerability, and drill bit stability. In example embodiments in which the drill string includes a rotary steerable tool, the system 60 may be further configured to receive rotary steerable tool (RSS) parameters. The system may include a plurality of trained machine learning (ML) models, for example, two, three, four, or more trained ML models configured to estimate a corresponding plurality of drill bit parameters. In one example embodiment, a first ML model is configured to estimate a rate of penetration (ROP) while drilling, a second ML model is configured to estimate a steerability parameter such as dog leg severity (DLS), and a third ML model is configured to estimate a stability parameter such as real bit acceleration (ACC). To perform these functions, the hardware may include one or more processors (e.g., microprocessors) which may be connected to one or more data storage devices (e.g., hard drives or solid state memory). As is known to those of ordinary skill, the processors may be further connected to a network, e.g., to receive the various sensor data from networked sensors) or another computer system. The system 60 may be further configured to receive the trained machine learning model(s). It will be further understood that the disclosed embodiments may include processor executable instructions stored in the data storage device. The executable instructions may be configured, for example, to execute method 100 to optimize the drill bit characteristics. It will, of course, be understood that the disclosed embodiments are not limited to the use of or the configuration of any particular computer hardware and/or software.

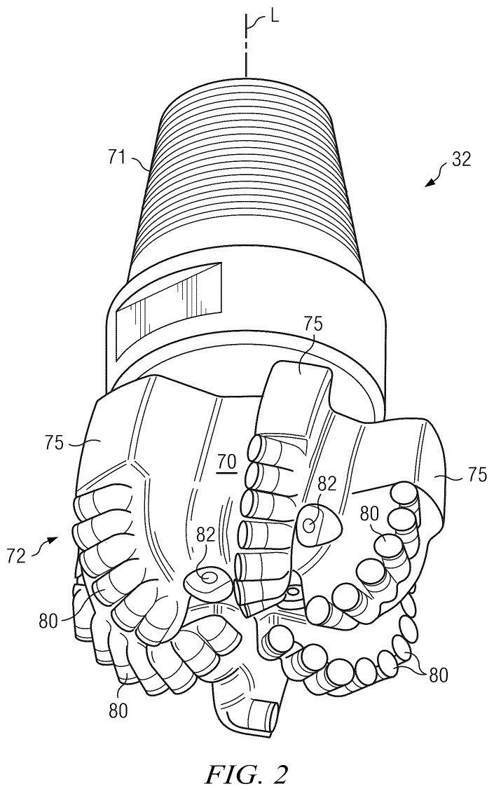

FIG. 2 depicts an example drill bit 32 that may be optimized using system 60. The depicted example drill bit 32 includes a bit body 70 having a threaded upper pin end 71 and a cutting end 72. The cutting end 72 may include a plurality of (e.g., from three to seven) ribs or blades 75 arranged about a rotational axis of the body 70. Each blade 75 may have a cone portion, a nose portion, a flank portion, and a gauge portion (not notated). A plurality of cutting elements (cutters) 80 may be deployed on or embedded in any portion of each of the blades 75 at predetermined angular orientations and radial locations relative to a working surface and with a desired back rake angle and side rake angle against a formation to be drilled. The drill bit 32 may further include a plurality of orifices 82 between the blades 75 on the bit body 70. The orifices 82 may be configured to receive nozzles for discharging drilling fluid into the wellbore. The fluid courses between the blades 75 may be configured (e.g., sized and shaped) to provide additional flow channels for drilling fluid and to provide a passage for formation cuttings to travel past the drill bit 32 towards the surface.

Optimizing a drill bit configuration is challenging and commonly requires the use of computationally demanding mathematical models and expert analysis. In some drilling operations, the drill bit may be selected based upon three key performance indicators (KPI); namely drill-ability, steerability, and stability. In practice, there is often a complex interaction between these three KPI, such that modifying various drill bit features to influence one of the performance indicators generally influences the other two (and often negatively). This complex interaction commonly requires a drill bit design team to make drill bit performance trade-offs, for example, selecting drill bit features that optimize one of the performance indicators at the expense of the others. Assessing a single design change can sometimes require multiple days of expert time such that drill bit optimization is a time consuming and expensive process. There is a need in the industry for improved methods that reduce the time and expense required to optimize a drill bit for a particular drilling operation.

FIG. 3 schematically depicts one example of the above-described three key drill bit performance indicators 90 (referred to herein as 3-KPI). The example 3-KPI 90 is depicted as a triangle in which a first corner 92 indicates drilling speed (e.g., rate of penetration), a second corner 94 indicates drilling stability, and a third corner 96 indicates drilling steerability. The depicted example 3-KPI 90 further includes arrows 93, 95, 97 indicating the complex interaction between each of the performance indicators, for example, the complex interaction between drilling speed and stability 93, the complex interaction between drilling speed and steerability 95, and the complex interaction between stability and steerability 97.

The disclosed embodiments make use of multiple trained machine learning (ML) models to optimize drill bit parameters for a particular drilling operation. The multiple ML models may be used, for example, to estimate corresponding drill bit performance metrics and their relationship to drill bit design parameters (as well as other drilling parameters). In one example embodiment, first and second distinct ML models are configured to estimate drilling speed and drilling steerability (two corners of the 3-KPI triangle depicted on FIG. 3). In another example embodiment, first, second, and third distinct ML models are configured to estimate drilling speed, drilling steerability, and drilling stability (each of the three corners of the 3-KPI triangle depicted on FIG. 2). In still another example embodiment, first, second, third, and fourth distinct ML models are configured to estimate drilling speed, drilling steerability, drilling stability, and drill bit durability. Output from the ML models may then be further evaluated to optimize a drill bit design for a particular drilling operation (e.g., an operation in a particular formation).

In the disclosed embodiments, various drill bit features may be digitized and combined with drilling parameters to construct ML models that describe drill bit performance, for example, according to the three KPI. In this way it may be possible to quantify and qualify the effect of each of the drill bit features on the drill bit KPIs. Moreover, as described in more detail below, the trained ML models may be used in an optimization algorithm to automatically generate optimized drill bits to maximize each or some combination of the KPIs.

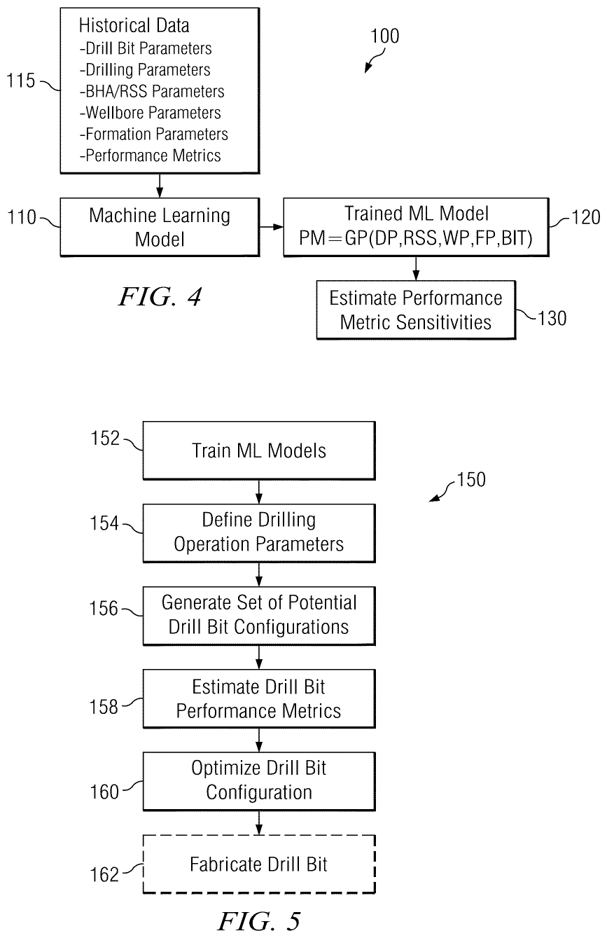

FIG. 4 depicts an example block diagram 100 of ML model training. The ML model (e.g., such as a Gaussian Processes ML model) is shown at 110. Historical data 115 from a large number of wells is input into the ML model 110 at 115. The historical data includes drilling operation parameters that may include drill bit parameters, drilling parameters, BHA and/or RSS parameters, wellbore parameters, formation parameters, and a measured drill bit performance metric (PM) such as ROP, DLS, or ACC. Example drill bit parameters are listed above and may include specified design information about the cutting elements on the drill bit (e.g., including the number of cutting elements, the spacing of the cutting elements, the angular orientation of the cutting elements, and the like). Example drilling parameters may include, for example, surface or downhole measured weight on bit (WOB), drilling fluid flow rate and/or pressure, collar or drill bit rotation rate, RSS steering ratio and toolface, RSS pad force, and surface rpm. Example wellbore parameters may include, for example, wellbore diameter, measured depth, inclination, azimuth, and curvature. Example BHA and/or RSS parameters may include, for example, drill string diameter, flex or stiffness, RSS type, RSS pad pressure, and the axial distance between the drill bit cutting surface and the RSS actuators. Example formation parameters may include various formation properties, such as rock hardness, fracture strength, porosity, and mechanical specific energy. Alternatively (and/or additionally), the formation parameters may include a formation listing particular formation lithologies such as sandstone, limestone, shale, dolomite, and the like, and/or a label describing a general field location such as Marcellus, Niobrara, Utica, Codell, and the like. The disclosed embodiments are, or course, not limited in these regards.

With continued reference to FIG. 4, the machine learning model 110 processes the historical drilling data 115 to generate a trained model 120 including relationships and/or correlations between a drill bit performance metric (PM) and the drill bit parameters, drilling parameters, BHA and/or RSS parameters, wellbore parameters, and/or formation parameters in the historical drilling data 115. Example drill bit performance metrics may include drilling speed or a rate of penetration (ROP) while drilling, drilling steerability or dogleg severity (DLS), drilling stability such as axial or lateral acceleration (ACC), and/or dill bit durability or wear. In the depicted example embodiment, the drill bit performance metric (PM) is expressed as being related to the drilling parameters DP, the RSS parameters, the wellbore parameters WP, the formation parameters FP, and the drill bit parameters BIT via a Gaussian Processes (GP) machine learning model.

With still further reference to FIG. 4, the trained machine learning model 120 may be further evaluated to estimate sensitivities of the PMs to changes in the drill bit parameters (as well as the other drilling and formation parameters) at 130. In one example embodiment, each of first, second, and third trained ML models may be evaluated to estimate sensitivities of the drilling speed, drilling steerability, and drilling stability to changes in the drill bit parameters. The evaluation may include, for example, a statistical analysis of the trained model to understand statistical relationships and correlations between the performance metrics and the drill bit parameters. The sensitivities may be in the mathematical form of a predictor weight and may indicate the individual sensitivities of a particular PM to the drill bit parameters. These sensitivities may then be further evaluated to optimize a drill bit configuration.

FIG. 5 depicts a flowchart of one example method 150 for optimizing a drill bit for a particular drilling operation. Method 150 includes training a plurality of ML models with historical drilling data at 152 to obtain a corresponding plurality of trained ML models. As described above, the historical drilling data may include substantially any suitable drilling data, for example, from a number of previously drilled wells, and may include a large number of drill bit, rotary steerable tool, drilling, and formation parameters as well as corresponding measured drill bit performance metrics PMs such as ROP, DLS, and ACC. The training may include identifying relationships and/or correlations between the historical drilling data and the measured drill bit performance metrics. Such training generally requires significant computing power and is often performed off-site (e.g., at computing facilities that are not on the rig site). However, the disclosed embodiments are not limited in this regard. In one example embodiment, first and second ML models are trained at 152, for example, a first ML model that estimates ROP and a second ML model that estimates DLS. In another example embodiment, first, second-, and third-ML models are trained at 152, for example, a first ML model that estimates ROP, a second ML model that estimates DLS, and a third ML model that estimates ACC. In still another example embodiment, first, second, third-, and fourth-ML models are trained at 152, for example, a first ML model that estimates ROP, a second ML model that estimates DLS, a third ML model that estimates ACC, and a fourth ML model that estimate drill bit durability or drill bit wear. It will be appreciated that in example embodiments that employ first, second-, and third-ML models, that an evaluation of drill bit durability or drill bit wear may be included in the ROP evaluation when depth is included as a model input (e.g., since ROP tends to deteriorate with increasing bit wear).

Drilling operation parameters may be obtained or defined at 154. The drilling operation parameters may include, for example, a listing of formation parameters or formations through which a well is to be drilled, a listing of the wellbore profile such as the wellbore diameter, the wellbore depth, the wellbore inclination, as well as target drilling metrics such as a target rate of penetration and target drilling parameters. The drilling operation parameters may further include information about the drill string, for example, including the BHA and/or RSS configuration.

With continued reference to FIG. 5, a set of potential drill bit configurations may be generated (or received) at 156. The set of potential drill bit configurations may include a listing, including a plurality of drill bit parameter values (features or characteristics) for each member of the set (each potential drill bit). The listed drill bit parameter values may include values for various features of a drill bit, for example, including one or more of an axial cutter count, a lateral inner cutter count, a lateral outer cutter count, a tipground cutter count, a lateral inner height, a lateral outer height, a tipground height, an axial backrake, a lateral outer backrake, a lateral inner backrake, a tipground backrake, and a bur. Such drill bit parameters are known to those of ordinary skill in the art. It will be appreciated that the set of potential drill bit configurations may be configured based upon sensitivities of the PMs to changes in the drill bit parameters estimated by evaluating the ML models. In example embodiments, drill bit parameters having lower sensitivities (below a threshold) may be held constant while those having higher sensitivities (above a threshold) may be varied or adjusted to obtain the set of potential drill bit configurations.

The drilling parameters (including drill string parameters) and formation parameters obtained at 154 and the drill bit parameters obtained at 156 may be input into the plurality of trained ML models at 158 to estimate corresponding drill bit performance metrics PM. As described above, in example embodiments, the plurality of trained ML models may include a first ML model that estimates ROP, a second ML model that estimates DLS, and a third ML model that estimates ACC. In such example embodiments, the drilling parameters, formation parameters, and drill bit parameters may be input into the first, second, and third trained ML models to obtain estimates of the drilling speed, drill bit stability, and drill bit steerability corresponding to each of the drill bit configurations in the set. An optimum (or desired) drill bit configuration may then be selected at 160 from the set of drill bit configurations based on the corresponding target drill bit performance metrics obtained at 158. Method 150 may further optionally include fabricating a drill bit at 162 according to the optimized drill bit configuration selected at 160.

As also described above with respect to FIG. 4, the ML models may be trained using historical drilling data. For example, a large data set may be created from hundreds (or even thousands) of drilling operations including up to one hundred (or more) different drill bit configurations. The collected data may include survey data acquired from an RSS and/or MWD tool, LWD data to assess the formation properties, well construction drilling parameters, as well as the drill bit configuration. In one example implementation, a historical data set including about 2000 drilling operations and over 100 different drill bit configurations was assembled. In this particular example implementation, each of the drilling operations made use of an SLB NeoSteer at bit steerable system. The historical data included several hundred thousand drilled surveys, as well as saved steering tool data, LWD formation evaluation data, drilling parameters, and the drill bit features.

The historical data may be utilized to train the ML models (e.g., the first, second, and third ML models). The historical data may be split into a training subset and a validation subset and then used to train the ML models. In such embodiments, the historical data is preferably split well by well such that the training subset and validation subset include historical data obtained from different (mutually exclusive) wells. The training may include identifying relationships and/or correlations between the drill bit, rotary steerable tool, drilling, and formation parameters and the corresponding target drill bit performance metrics. The training and validation may further include tuning model hyper parameters and optimizing to achieve the lowest mean absolute percentage error (MAPE). The training may make use of customized deep learning architectures suitable for regression and may further compare and contrast the predictive performance of many different artificial intelligence (AI) or machine learning based regression methods including, for example, linear regression, decision trees, gradient boosting, random forest, neural networks, recurrent neural networks, convolutional neural networks, feed forward neural networks, and transformer networks, as well as an ensemble of the best performing models to define which is the best performing architecture.

In certain advantageous embodiments, the ML model may include a Gaussian Processes (GP) machine learning model. GP models have been found to advantageously provide superior accuracy as well as to advantageously provide confidence intervals (e.g. error bands) for the PM estimate. In example embodiments that make use of first, second, and third ML models, it has been found that the GP models provide DLS estimates having the tightest confidence interval, followed by ROP estimates and ACC estimates. However, the disclosed embodiments are not limited in these regards.

In example embodiments, the training may include training first and second, first, second, and third, or first, second, third, and fourth ML models. For example, a first ML model may be trained to identify first relationships and/or correlations between the drill bit, rotary steerable tool, drilling, and formation parameters and the rate of penetration while drilling (ROP). A second ML model may be trained to identify second relationships and/or correlations between the drill bit, rotary steerable tool, drilling, and formation parameters and a steerability metric such as dogleg severity (DLS). A third ML model may be trained to identify third relationships and/or correlations between the drill bit, rotary steerable tool, drilling, and formation parameters and a stability metric such as lateral acceleration while drilling (ACC). These example first, second-, and third-ML models may be expressed mathematically, as follows:

$$ROP = ML 1 ( DP , FP , RSS , BIT )$$

$$DLS = ML 2 ( DP , FP , RSS , BIT )$$

$$ACC = ML 3 ( DP , FP , RSS , BIT )$$

where ML1, ML2, and ML3 represent the first, second, and third trained ML models, DP represents the drilling parameters, FP represents the formation parameters, RSS represents the steering tool parameters, and BIT represents the drill bit parameters.

While not depicted in FIGS. 4 and 5, it will be appreciated that training the ML models may further include gathering the historical dataset of downhole synchronized data for many drilling operations including multiple wells and multiple oilfields. The dataset may be cleansed and pre-processed to remove outliers and other poor quality data.

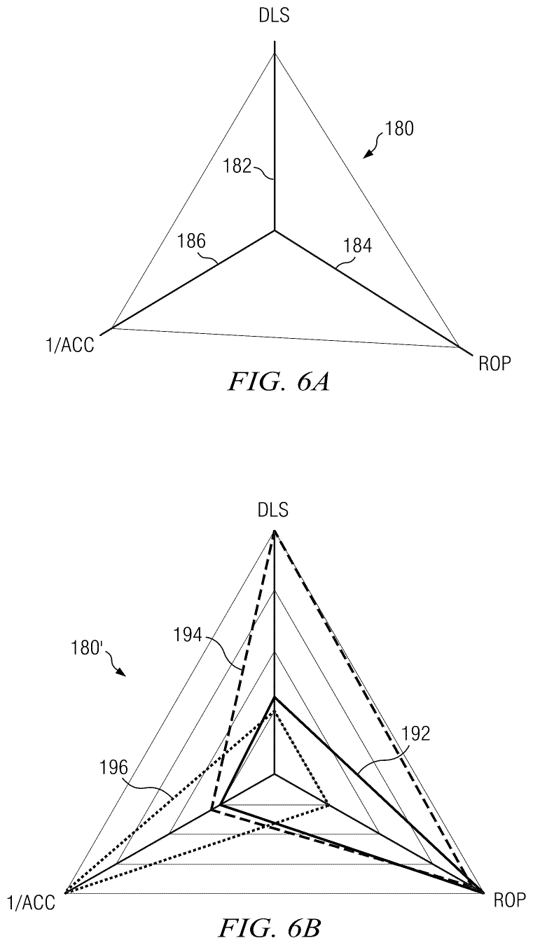

With reference now to FIGS. 6A and 6B (collectively FIG. 6), and with still further reference to FIGS. 4 and 5, the target drill bit performance metrics (e.g., ROP, DLS, and ACC) may be estimated at 158 using the trained ML models for a particular drill bit configuration (as well as the drilling and formation parameters). FIG. 6A depicts an example triangular representation 180 of the 3-KPI for one example drill bit configuration. In this example, the estimated ROP is shown on the vertical axis 182, the DLS is shown on the righthand axis 184, and 1/ACC (inverse ACC) is shown on the lefthand axis 186 of the triangular axes. Note that the size of the depicted triangle increases as the ROP and DLS increase and as ACC decreases (1/ACC increases).

FIG. 6B depicts example triangular representations 180′ of the 3-KPI for three example drill bit configurations. In this example, the first and second drill bit configurations 192 and 194 achieve a relatively high ROP. The third drill bit configuration 196 achieves a lower ROP. The first drill bit configuration 192 is the most stable, but has the lowest steerability. The second drill bit configuration 194 has the highest steerability, but has low stability. The third drill bit configuration 196 also has a high steerability and stability, but lower ROP as noted above.

With still further reference to FIGS. 4-6, an optimum (or desired) drill bit configuration may be selected at 110 from the set of drill bit configurations based on the drill bit performance metrics estimated at 158. The optimum drill bit configuration may be selected based on substantially any selection criteria. For example, the optimum drill bit configuration may be the configuration having the highest average (or weighted average) of the estimated performance metrics, or the highest average value (or weighted average) of the configurations for which each of the estimated performance metrics is greater than a corresponding threshold. With respect to FIG. 6, the optimum drill bit configuration may be the configuration that achieves the highest triangular perimeter or area in the 3-KPI or the configuration that achieves the highest triangular perimeter or area in the 3-KPI for which each of the estimated performance metrics is greater than a corresponding threshold. The disclosed embodiments are, of course, not limited to any particular selection criteria.

It will be appreciated that drill bits often have a large number of design parameters, including, for example, the multiple parameters listed above. Drill bit optimization can therefore be a high dimensional problem such that the set of drill bit configurations can become unmanageably large. For example, generating a set of drill bit configurations for a drill bit including 12 parameters with 10 levels per parameter results in a set including 1012 (one trillion) distinct drill bits. Moreover the number of bits increases rapidly with increasing parameters and levels. Computing a brute force optimization may therefore be overly expensive in time and computing resources.

The set of drill bit configurations evaluated to obtain the used to optimum (or desired) drill bit configuration may advantageously include a large but manageable number of drill bit configurations, for example, including several hundred or thousand drill bit configurations. In one example implementation, the set of potential drill bit configurations may include high and low values for each of the drill bit parameters. It will be appreciated that for a drill bit including N parameters, the total number of drill bit configurations is 2^{N} (e.g., 64 for N=6, 256 for N=8, and 1024 for N=10).

In other advantageous implementations, drill bit parameters having lower sensitivities (below a threshold) may be held constant while those having higher sensitivities (above a threshold) may be varied or adjusted to obtain the set of potential drill bit configurations. For example, the set of potential drill bit configurations may include four levels for each of the drill bit parameters having a sensitivity above a threshold and a single (constant) level for drill bit parameters less than the threshold. It will be appreciated that for a drill bit in which N parameters have a sensitivity greater than the threshold; the total number of drill bit configurations is 4^{N} (e.g., 64 for N=3, 256 for N=4, and 1024 for N=5).

In still further alternative and advantageous implementations, drill bit parameters having the highest sensitivities may include more levels while those having a moderate sensitivity may have fewer levels. For example, the set of potential drill bit configurations may include ten levels for each of the two drill bit parameters having the highest sensitivities, two levels (high and low) for each of the other drill bit parameters that have a sensitivity above a threshold and a single (constant) level for drill bit parameters less than the threshold. It will be appreciated that for a drill bit in which N parameters have a sensitivity greater than the threshold; the total number of drill bit configurations is 100·2^{N-2} (e.g., 200 for N=3, 400 for N=4, and 800 for N=5).

It will be understood that the present disclosure includes numerous embodiments. These embodiments include, but are not limited to, the following embodiments.

In a first embodiment, a method for optimizing a drill bit for a drilling operation includes training a plurality of machine learning (ML) models with historical drilling data to obtain a corresponding plurality of trained ML models, wherein each of the trained ML models is configured to estimate a drill bit performance metric; obtaining drilling operation parameters for the drilling operation, wherein the drilling operation parameters include at least one of drilling parameters, formation parameters, and bottom hole assembly parameters; generating drill bit parameters for each of a plurality of potential drill bit configurations; inputting the obtained drilling operation parameters and the generated drill bit parameters into the plurality of trained ML models to estimate a corresponding plurality of drill bit performance metrics; and selecting an optimum drill bit configuration from the set of potential drill bit configurations based on the estimated drill bit performance metrics obtained from plurality of trained ML models.

A second embodiment may include the first embodiment, further comprising fabricating the optimized drill bit according to the optimized drill bit configuration.

A third embodiment may include any one of the first or second embodiments, wherein the historical drilling data comprise the drill bit parameters, drilling parameters, bottom hole assembly parameters, wellbore parameters, formation parameters and the corresponding drill bit performance metrics.

A fourth embodiment may include any one of the first through third embodiments, wherein the training comprises obtaining a historical data set including drilling data obtained from a plurality of wellbores; splitting the historical data set into a training subset and a validation subset, wherein the historical data set is split wellbore by wellbore such that the training subset and validation subset include data obtained from mutually exclusive wells; training the plurality of machine learning (ML) models using the training subset; and validating each of the trained ML models using the validation subset.

A fifth embodiment may include any one of the first through fourth embodiments, wherein the plurality of ML models comprises first and second ML models, the first ML model configured to estimate drilling speed and the second ML model configured to estimate drill bit steerability.

A sixth embodiment may include the fifth embodiment, wherein the plurality of ML models comprises first, second, and third ML models, the third ML model configured to estimate drill bit stability.

A seventh embodiment may include the sixth embodiment, wherein the selecting an optimum drill bit configuration comprises (i) generating a triangle from the estimated drilling speed, the estimated drill bit steerability, and the estimated drill bit stability for each of the plurality of drill bit configurations and (ii) selecting the drill bit configuration for which the generated triangle has the greatest perimeter or area.

An eighth embodiment may include any one of the first through seventh embodiments, wherein each of the plurality of ML models comprises a Gaussian Processes ML model.

A ninth embodiment may include any one of the first through eighth embodiments, further comprising evaluating the trained ML models to determine sensitivities of the plurality of drill bit performance metrics to the drill bit parameters.

A tenth embodiment may include the ninth embodiment, wherein the generating the drill bit parameters comprises generating a plurality of drill bit parameter levels for each the drill bit parameters that has a sensitivity greater than a threshold.

In an eleventh embodiment a system for optimizing a drill bit for a drilling operation includes a plurality of trained machine learning (ML) models, wherein each of the trained ML models is configured to estimate a drill bit performance metric from drill bit parameters; and a processor configured to: receive drilling operation parameters for the drilling operation, wherein the drilling operation parameters include at least one of drilling parameters, formation parameters, and bottom hole assembly parameters; generate drill bit parameters for each of a plurality of potential drill bit configurations; use the plurality of trained ML models to estimate a corresponding plurality of drill bit performance metrics from the received drilling operation parameters and the generated drill bit parameters; and selecting an optimum drill bit configuration from the set of potential drill bit configurations based on the estimated drill bit performance metrics.

A twelfth embodiment may include the eleventh embodiment, wherein the plurality of ML models comprises first, second, and third ML models, the first ML model configured to estimate drilling speed, the second ML model configured to estimate drill bit steerability, and the third ML model configured to estimate drill bit stability.

A thirteenth embodiment may include the twelfth embodiment, wherein the processor is configured to select the optimum drill bit configuration via (i) generating a triangle from the estimated drilling speed, the estimated drill bit steerability, and the estimated drill bit stability for each of the plurality of drill bit configurations and (ii) selecting the drill bit configuration for which the generated triangle has the greatest perimeter or area.

A fourteenth embodiment may include any one of the eleventh through thirteenth embodiments, wherein each of the plurality of ML models comprises a Gaussian Processes ML model.

A fifteenth embodiment may include any one of the eleventh through fourteenth embodiments, wherein the processor is further configured to evaluate the trained ML models to determine sensitivities of the plurality of drill bit performance metrics to the drill bit parameters.

In a sixteenth embodiment a method for optimizing a drill bit for a drilling operation includes training a plurality of machine learning (ML) models with historical drilling data including drilling operation parameters to obtain a corresponding plurality of trained ML models, wherein each of the trained ML models is configured to estimate a drill bit performance metric from received drilling operation parameters, the received drilling operation parameters including at least drill bit parameters; evaluating the trained ML models to determine sensitivities of the drill bit performance metric to the drill bit parameters; and using the sensitivities of the drill bit parameters to optimize a drill bit.

A seventeenth embodiment may include the sixteenth embodiment, further comprising fabricating the optimized drill bit.

An eighteenth embodiment may include any one of the sixteenth through seventeenth embodiments, wherein the plurality of ML models comprises first, second, and third ML models, the first ML model configured to estimate drilling speed, the second ML model configured to estimate drill bit steerability, and the third ML model configured to estimate drill bit stability.

A nineteenth embodiment may include any one of the sixteenth through eighteenth embodiments, wherein the drilling operation parameters comprise the drill bit parameters, drilling parameters, bottom hole assembly parameters, wellbore parameters, formation parameters and the corresponding drill bit performance metrics.

A twentieth embodiment may include any one of the sixteenth through nineteenth embodiments, wherein the using the sensitivities comprises: selecting a drill bit parameter having a sensitivity greater than a threshold; and adjusting the drill bit parameter to optimize the drill bit.

Although a drill bit optimizer has been described in detail, it should be understood that various changes, substitutions and alternations can be made herein without departing from the spirit and scope of the disclosure as defined by the appended claims.

1. A method for optimizing a drill bit for a drilling operation, the method comprising:
training a plurality of machine learning (ML) models with historical drilling data to obtain a corresponding plurality of trained ML models, wherein each of the trained ML models is configured to estimate a drill bit performance metric;
obtaining drilling operation parameters for the drilling operation, wherein the drilling operation parameters include at least one of drilling parameters, formation parameters, and bottom hole assembly parameters;
generating drill bit parameters for each of a plurality of potential drill bit configurations;
inputting the obtained drilling operation parameters and the generated drill bit parameters into the plurality of trained ML models to estimate a corresponding plurality of drill bit performance metrics; and
selecting an optimum drill bit configuration from the set of potential drill bit configurations based on the estimated drill bit performance metrics obtained from the plurality of trained ML models.

2. The method of claim 1, further comprising fabricating the optimized drill bit according to the optimized drill bit configuration.

3. The method of claim 1, wherein the historical drilling data comprise the drill bit parameters, drilling parameters, bottom hole assembly parameters, wellbore parameters, formation parameters and the corresponding drill bit performance metrics.

4. The method of claim 1, wherein the training comprises:
obtaining a historical data set including drilling data obtained from a plurality of wellbores;
splitting the historical data set into a training subset and a validation subset, wherein the historical data set is split wellbore by wellbore such that the training subset and validation subset include data obtained from mutually exclusive wells;
training the plurality of machine learning (ML) models using the training subset; and
validating each of the trained ML models using the validation subset.

5. The method of claim 1, wherein the plurality of ML models comprises first and second ML models, the first ML model configured to estimate drilling speed and the second ML model configured to estimate drill bit steerability.

6. The method of claim 5, wherein the plurality of ML models comprises first, second, and third ML models, the third ML model configured to estimate drill bit stability.

7. The method of claim 6, wherein the selecting an optimum drill bit configuration comprises (i) generating a triangle from the estimated drilling speed, the estimated drill bit steerability, and the estimated drill bit stability for each of the plurality of drill bit configurations and (ii) selecting the drill bit configuration for which the generated triangle has the greatest perimeter or area.

8. The method of claim 1, wherein each of the plurality of ML models comprises a Gaussian Processes ML model.

9. The method of claim 1, further comprising evaluating the trained ML models to determine sensitivities of the plurality of drill bit performance metrics to the drill bit parameters.

10. The method of claim 9, wherein the generating the drill bit parameters comprises generating a plurality of drill bit parameter levels for each the drill bit parameters that has a sensitivity greater than a threshold.

11. A system for optimizing a drill bit for a drilling operation, the system comprising:
a plurality of trained machine learning (ML) models, wherein each of the trained ML models is configured to estimate a drill bit performance metric from drill bit parameters; and
a processor configured to:
receive drilling operation parameters for the drilling operation, wherein the drilling operation parameters include at least one of drilling parameters, formation parameters, and bottom hole assembly parameters;
generate drill bit parameters for each of a plurality of potential drill bit configurations;
use the plurality of trained ML models to estimate a corresponding plurality of drill bit performance metrics from the received drilling operation parameters and the generated drill bit parameters; and
selecting an optimum drill bit configuration from the set of potential drill bit configurations based on the estimated drill bit performance metrics.

12. The system of claim 11, wherein the plurality of ML models comprises first, second, and third ML models, the first ML model configured to estimate drilling speed, the second ML model configured to estimate drill bit steerability, and the third ML model configured to estimate drill bit stability.

13. The system of claim 12, wherein the processor is configured to select the optimum drill bit configuration via (i) generating a triangle from the estimated drilling speed, the estimated drill bit steerability, and the estimated drill bit stability for each of the plurality of drill bit configurations and (ii) selecting the drill bit configuration for which the generated triangle has the greatest perimeter or area.

14. The system of claim 11, wherein each of the plurality of ML models comprises a Gaussian Processes ML model.

15. The system of claim 11, wherein the processor is further configured to evaluate the trained ML models to determine sensitivities of the plurality of drill bit performance metrics to the drill bit parameters.

16. A method for optimizing a drill bit for a drilling operation, the method comprising:
training a plurality of machine learning (ML) models with historical drilling data including drilling operation parameters to obtain a corresponding plurality of trained ML models, wherein each of the trained ML models is configured to estimate a drill bit performance metric from received drilling operation parameters, the received drilling operation parameters including at least drill bit parameters;
evaluating the trained ML models to determine sensitivities of the drill bit performance metric to the drill bit parameters;
using the sensitivities of the drill bit parameters to optimize a drill bit.

17. The method of claim 16, further comprising fabricating the optimized drill bit.

18. The method of claim 16, wherein the plurality of ML models comprises first, second, and third ML models, the first ML model configured to estimate drilling speed, the second ML model configured to estimate drill bit steerability, and the third ML model configured to estimate drill bit stability.

19. The method of claim 16, wherein drilling operation parameters comprise the drill bit parameters, drilling parameters, bottom hole assembly parameters, wellbore parameters, formation parameters and the corresponding drill bit performance metrics.

20. The method of claim 16, wherein the using the sensitivities comprises:
selecting a drill bit parameter having a sensitivity greater than a threshold; and
adjusting the drill bit parameter to optimize the drill bit.
